(19) United States
(12) Patent Application Publication
(10) Pub. No.: US 2018/0226132 A1
(43) Pub. Date: Aug. 9, 2018

(54) SHIFT REGISTER AND OPERATION METHOD THEREOF

(71) Applicants: BOE TECHNOLOGY GROUP CO., LTD., Beijing (CN); BEIJING BOE DISPLAY TECHNOLOGY CO., LTD., Beijing (CN)

(72) Inventors: Yingqiang GAO, Beijing (CN); Huabin CHEN, Beijing (CN)

(21) Appl. No.: 15/541,893

(22) PCT Filed: Jan. 11, 2017
(86) PCT No.: PCT/CN2017/070865

§ 371 Date: Jul. 6, 2017

(30) Foreign Application Priority Data
May 16, 2016 (CN) 201610323870.1

(51) Int. Cl. G11C 19/28; G09G 3/36

(52) U.S. Cl. CPC G11C 19/28; G09G 2310/0286; G09G 3/3677

(57) ABSTRACT

A shift register and an operation method thereof. The shift register includes an input circuit, connected with an input terminal of the shift register and a pull-up node; a reset circuit, connected with a reset signal terminal, the pull-up node, a first power-supply voltage terminal, and an output terminal of the shift register; a pull-down control circuit, connected with a first clock signal terminal, the pull-up node, a pull-down node, and the first power-supply voltage terminal; a pull-down circuit, connected with the pull-down node, the output terminal of the shift register, the pull-up node, and the first power-supply voltage terminal; an output circuit, connected with the pull-up node, a second clock signal terminal, and the output terminal of the shift register; and a noise reduction circuit, connected with the pull-down node and configured for reducing noise at the output terminal.

### TECHNICAL FIELD

The present disclosure relates to a shift register and an operation method thereof.

### BACKGROUND

Thin film transistor liquid crystal displays (TFT-LCD) are widely used in various fields of production and life, which display by using a matrix arranged with M*N dots and being scanned row by row. When a TFT-LCD is displaying, a driving circuit drives respective pixels in a display panel, so that the TFT-LCD displays. A driving circuit of the TFT-LCD mainly includes a gate driving circuit and a data driving circuit, where the data driving circuit is used for sequentially latching inputted data according to a clock signal periodically, and converting the latched data into an analog signal and then inputting the analog signal to a data line of the display panel. The gate driving circuit is usually implemented by shift registers, and each shift register converts the clock signal into an on/off voltage, and respectively outputs the same to a respective gate line of the display panel. A gate line on the display panel is usually abutted with one shift register (i.e., a stage of the shift registers). A row-by-row scanning of the pixels in the display panel is implemented by enabling the respective shift registers to sequentially output the on voltage in turn.

On the other hand, with development of flat-panel displays, a high resolution and narrow frame become a development trend. With respect to the trend, a Gate Driver on Array (GOA) technology emerges. In the GOA technology, a gate driving circuit of the TFT-LCD is directly integrated on an array substrate, so as to replace a driving chip fabricated by a silicon chip bonded on an outer edge of the panel. By using the technology, the driving circuit can be directly fabricated on the array substrate, and it does not need to bond an integrated circuit (IC) and wiring around the panel any longer, which reduces a fabrication process of the panel, reduces product costs, and at the same time improves an integration level of the TFT-LCD panel. Thus, a narrow frame and high resolution is implemented for the panel.

### SUMMARY

According to one aspect of the disclosure, a shift register is provided, comprising:

an input circuit, including a first terminal connected with an input terminal of the shift register for receiving an input signal from the input terminal and a second terminal connected with a pull-up node;

a reset circuit, including a first terminal connected with a reset signal terminal, a second terminal connected with the pull-up node, a third terminal connected with a first power-supply voltage terminal, and a fourth terminal connected with an output terminal of the shift register;

a pull-down control circuit, including a first terminal connected with a first clock signal terminal, a second terminal connected with the pull-up node, a third terminal connected with a pull-down node, and a fourth terminal connected with the first power-supply voltage terminal;

a pull-down circuit, including a first terminal connected with the pull-down node, a second terminal connected with the output terminal of the shift register, a third terminal connected with the pull-up node, and a fourth terminal connected with the first power-supply voltage terminal;

an output circuit, including a first terminal connected with the pull-up node, a second terminal connected with a second clock signal terminal, and a third terminal connected with the output terminal of the shift register; and

a noise reduction circuit, connected with the pull-down node and configured for reducing noise at the output terminal of the shift register by maintaining a voltage level of the pull-down node.

According to another aspect of the disclosure, an operation method of a shift register is provided. The shift register comprises an input circuit, a reset circuit, a pull-down control circuit, a pull-down circuit, an output circuit and a noise reduction circuit. The method comprises:

transmitting, by the input circuit, a received input signal to a pull-up node;

pulling down, by the reset circuit, a pull-up signal at the pull-up node to a power-supply voltage of a first power-supply voltage terminal, and pulling down an output signal of an output terminal of the shift register to a power-supply voltage of the first power-supply voltage terminal;

controlling, by the pull-down control circuit, whether the pull-down circuit operates or not;

pulling down, by the pull-down circuit, the output terminal and the pull-up node of the shift register to the power-supply voltage of the first power-supply voltage terminal;

outputting, by the output circuit, a second clock signal of a second clock signal terminal to the output terminal of the shift register; and

reducing, by the noise reduction circuit, noise at the output terminal of the shift register through maintaining a voltage level of a pull-down node.

### BRIEF DESCRIPTION OF THE DRAWINGS

FIG. 1 shows a circuit diagram of an example shift register;

FIG. 2 shows a timing chart of respective signals when the shift register in FIG. 1 is scanning;

FIG. 3 shows a block diagram of a shift register according to an embodiment of the present disclosure;

FIG. 4 shows an exemplary circuit structural diagram of a shift register according to an embodiment of the present disclosure;

FIG. 5 shows another exemplary circuit structural diagram of a shift register according to an embodiment of the present disclosure;

FIG. 6 shows yet another exemplary circuit structural diagram of a shift register according to an embodiment of the present disclosure;

FIG. 7 shows an operation timing chart of the exemplary circuit of the shift register in FIG. 6.

### DETAILED DESCRIPTION

Hereafter, the technical solutions of the embodiments of the present disclosure will be described in a clearly and fully understandable way ill connection with the drawings related to the embodiments of the disclosure. It is obvious that the described embodiments are just a part but not all of the embodiments of the present disclosure. Based on embodiments of the present disclosure, all other embodiments obtained by those skilled in the art without making other inventive work should be within the scope of the present disclosure.

All transistors used in embodiments of the present disclosure may be thin film transistors or field effect transistors, or other devices having same characteristics. In these embodiments, connection modes of a drain electrode and a source electrode of each transistor are interchangeable, and thus, there is no difference between the drain electrode and the source electrode of the respective transistor in the embodiments of the present disclosure. Here, only in order to distinguish two electrodes of a transistor from a gate electrode, one electrode thereof is referred to as a drain electrode and the other is referred to as a source electrode.

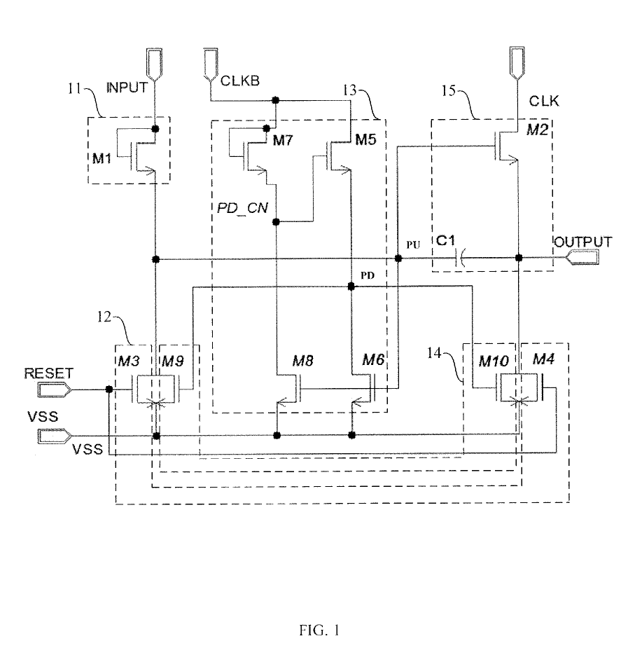

FIG. 1 shows a circuit diagram of an example shift register. As shown in FIG. 1, the shift register 100 comprises a first transistor to a tenth transistor M1 to M10 and a first capacitor C1, where the first transistor M1 serves as an input circuit 11, the third transistor M3 and the fourth transistor M4 serve as a reset circuit 12, the fifth transistor M5 to the eighth transistor M8 serve as a pull-down control circuit 13, the ninth transistor and the tenth transistor M9 to M10 serve as a pull-down circuit 14, and the second transistor M2 and the first capacitor C1 serve as an output circuit 15.

The input circuit 11A has a first terminal connected with an input terminal INPUT of the shift register, for receiving an input signal from the input terminal INPUT, and a second terminal connected with a pull-up node PU; and the input circuit 11 is configured to transmit the received input signal to the pull-up node PU, when the input signal of the input terminal INPUT is at an active input level.

The reset circuit 12 has a first terminal connected with a reset signal terminal RESET, a second terminal connected with the pull-up node PU, a third terminal connected with a first power-supply voltage terminal VSS, and a fourth terminal connected with an output terminal OUTPUT. When the reset signal of the reset signal terminal RESET is at an active control level, the reset circuit 12 is configured to pull down the pull-up signal at the pull-up node PU to a power-supply voltage of the first power-supply voltage terminal VSS and to pull down the output signal of the output terminal OUTPUT to the power-supply voltage of the first power-supply voltage terminal VSS.

The pull-down control circuit 13 has a first terminal connected with a first clock signal terminal CLKB, a second terminal connected with the pull-up node PU, a third terminal connected with the pull-down node PD, and a fourth terminal connected with the first power-supply voltage terminal VSS; and the pull-down control circuit 13 is configured to control whether the pull-down circuit 14 operates or not. For example, the pull-down control circuit 13 generates a pull-down signal with a non-active pull-down level at the pull-down node PD, when the pull-up signal at the pull-up node PU is at an active pull-up level; and the pull-down control circuit 13 generates a pull-down signal with an active pull-down level at the pull-down node PD, when the pull-up signal at the pull-up node PU is at a non-active pull-up level and a first clock signal at the first clock signal terminal CLKB is at the active control level. The pull-down circuit 14 has a first terminal connected with the pull-down node PD, a second terminal connected with the output terminal OUTPUT, a third terminal connected with the pull-up node PU, and a fourth terminal connected with the first power-supply voltage terminal VSS. The pull-down circuit 14 is configured to pull down the output terminal OUTPUT and the pull-up node PU to the power-supply voltage of the first power-supply voltage terminal VSS, when the pull-down signal at the pull-down node PD is at the active pull-down level.

The output circuit 15 has a first terminal connected with the pull-up node PU, a second terminal connected with a second clock signal terminal CLK, and a third terminal connected with the output terminal OUTPUT of the shift register. The output circuit 15 is configured to output a second clock signal of the second clock signal terminal CLK to the output terminal OUTPUT, when the pull-up signal at the pull-up node PU is at the active pull-up level.

For example, the first clock signal of the first clock signal terminal CLKB and the second clock signal of the second clock signal terminal CLK have inverted phases.

For example, the first power-supply voltage terminal VSS is a low power-supply voltage terminal.

Hereinafter, description is given to a case where the above-described transistors are all N-type transistors as an example.

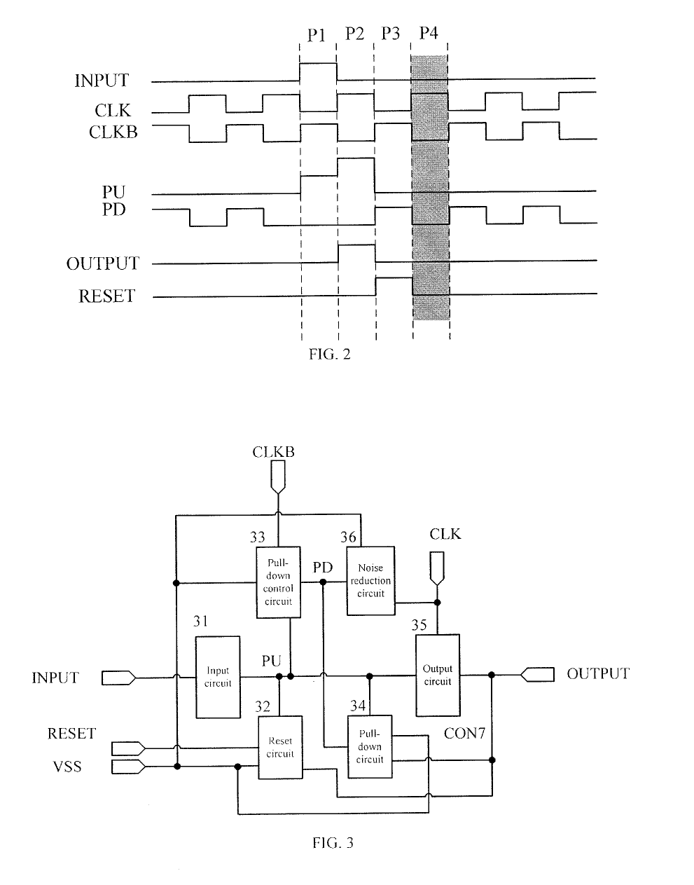

FIG. 2 shows a timing chart of respective signals when the shift register of FIG. 1 is scanning. As shown in FIG. 2, with respect to the shift register in FIG. 1, when it is in a holding phase (i.e., a fourth phase P4 in FIG. 2), the pull-up node PU and the output terminal OUTPUT are in a suspended state, which is very likely to introduce noise and affect voltage holding.

For example, in the holding phase, the second clock signal of the second clock signal terminal CLK is turned from a low voltage level of a reset phase (i.e., a third phase P3 in FIG. 2) to a high voltage level; due to existence of a gate source capacitor Cgs of the second transistor M2, a voltage of the pull-up node PU is pulled up, and the second transistor M2 is turned on, so that the second clock signal of the second clock signal terminal CLK recharges the output terminal OUTPUT, and noise is introduced to the output terminal.

To solve the above-described problem, in the present disclosure anew shift register is proposed, which can effectively reduce the noise at the output terminal.

FIG. 3 shows a block diagram of a shift register according to an embodiment of the present disclosure. As shown in FIG. 3, in an embodiment, the shift register comprises an input circuit 31, a reset circuit 32, a pull-down control circuit 33, a pull-down circuit 34, an output circuit 35 and a noise reduction circuit 36.

The input circuit 31 has a first terminal connected with an input terminal INPUT of the shift register for receiving an input signal from the input terminal INPUT, and a second terminal connected with a pull-up node PU; and the input circuit 31 is configured to transmit the received input signal to the pull-up node PU, when the input signal of the input terminal INPUT is at an active input level.

The reset circuit 32 has a first terminal connected with a reset signal terminal RESET, a second terminal connected with the pull-up node PU, a third terminal connected with a first power-supply voltage terminal VSS, and a fourth terminal connected with an output terminal OUTPUT. The reset circuit 32 is configured to pull down a pull-up signal at the pull-up node PU to a power-supply voltage of the first power-supply voltage terminal VSS and to pull down an output signal of the output terminal OUTPUT to the power-supply voltage of the first power-supply voltage terminal VSS, when a reset signal of the reset signal terminal RESET is at an active control level.

The pull-down control circuit 33 has a first terminal connected with a first clock signal terminal CLKB, a second terminal connected with the pull-up node PU, a third terminal connected with the pull-down node PD, and a fourth terminal connected with the first power-supply voltage terminal VSS; and the pull-down control circuit 33 is configured to control the pull-down circuit 34 whether to operate or not. For example, the pull-down control circuit 33 generates a pull-down signal with a non-active pull-down level at the pull-down node PD, when the pull-up signal at the pull-up node PU is at the active pull-up level; and the pull-down control circuit 33 generates a pull-down signal with an active pull-down level at the pull-down node PD, when the pull-up signal at the pull-up node PU is at the non-active pull-up level and the first clock signal at the first clock signal terminal CLKB is at the active control level.

The pull-down circuit 34 has a first terminal connected with the pull-down node PD, a second terminal connected with the output terminal OUTPUT, a third terminal connected with the pull-up node PU, and a fourth terminal connected with the first power-supply voltage terminal VSS; and the pull-down circuit 34 is configured to pull down the output terminal OUTPUT and the pull-up node PU to the power-supply voltage of the first power-supply voltage terminal VSS, when the pull-down signal at the pull-down node PD is at the active pull-down level.

The output circuit 35 has a first terminal connected with the pull-up node PU, a second terminal connected with a second clock signal terminal CLK, and a third terminal connected with the output terminal OUTPUT of the shift register; and the output circuit 35 is configured to output a second clock signal of the second clock signal terminal CLK to the output terminal OUTPUT, when the pull-up signal at the pull-up node PU is at the active pull-up level.

The noise reduction circuit 36 is connected with the pull-down node PD, and the noise reduction circuit 36 is configured to reduce the noise at the output terminal of the shift register by maintaining a voltage level of the pull-down node. Further, the noise reduction circuit 36 is also connected with the first power-supply voltage terminal VSS and/or with the second clock signal terminal CLK.

For example, the first clock signal of the first clock signal terminal CLKB and the second clock signal of the second clock signal terminal CLK have inverted phases.

For example, the first power-supply voltage terminal VSS is a low power-supply voltage terminal.

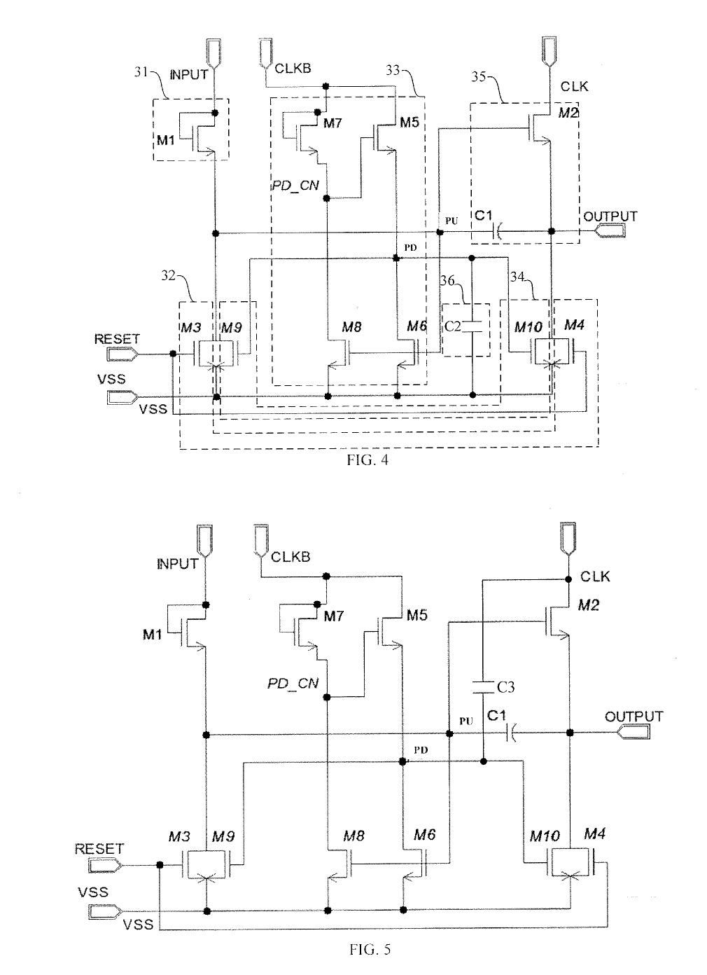

FIG. 4 shows an exemplary circuit structural diagram of a shift register according to an embodiment of the present disclosure. Hereinafter, description is given to a case where the transistors in FIG. 4 are all N-type transistors which are respectively turned on when high voltage levels are inputted to their respective gate electrodes.

As shown in FIG. 4, in an embodiment, for example, the input circuit 31 includes an input transistor M1, a gate electrode and a first electrode of the input transistor M1 are connected with the input terminal INPUT, and a second electrode of the input transistor M1 is connected with the pull-up node PU. When the input signal of the input terminal INPUT is at the high voltage level, the input transistor M1 is turned on and transmits the input signal of the input terminal INPUT to the pull-up node PU.

In an embodiment, for example, the reset circuit 32 includes a node reset transistor M3 and an output reset transistor M4. A gate electrode of the node reset transistor M3 is connected with the reset signal terminal RESET, a first electrode is connected with the pull-up node PU, and a second electrode is connected with the first power-supply voltage terminal VSS. A gate electrode of the output reset transistor M4 is connected with the reset signal terminal RESET, a first electrode is connected with the output terminal OUTPUT, and a second electrode is connected with the first power-supply voltage terminal VSS. When the reset signal at the reset signal terminal RESET is at the high voltage level, the node reset transistor M3 is turned on, to pull down the pull-up signal at the pull-up node PU to the power-supply voltage of the first power-supply voltage terminal VSS; and the output reset transistor M4 is turned on, to pull down the output signal of the output terminal OUTPUT to the power-supply voltage of the first power-supply voltage terminal VSS.

In an embodiment, for example, the pull-down control circuit 33 includes a first pull-down control transistor M5, a second pull-down control transistor M6, a third pull-down control transistor M7, and a fourth pull-down control transistor M8. A gate electrode of the first pull-down control transistor M5 is connected with a pull-down control node PD_CN, a first electrode is connected with the first clock signal terminal CLKB, and a second electrode is connected with the pull-down node PD. A gate electrode of the second pull-down control transistor M6 is connected with the pull-up node PU, a first electrode is connected with the pull-down node PD, and a second electrode is connected with the first power-supply voltage terminal VSS. A gate electrode and a first electrode of the third pull-down control transistor M7 are connected with the first clock signal terminal CLKB, and a second electrode is connected with the pull-down control node PD_CN. A gate electrode of the fourth pull-down control transistor M8 is connected with the pull-up node PU, a first electrode is connected with the pull-down control node PD_CN, and a second electrode is connected with the first power-supply voltage terminal VSS.

In an embodiment, for example, the pull-down circuit 34 includes a node pull-down transistor M9 and an output pull-clown transistor M10. Gate electrodes of the node pull-down transistor M9 and the output pull-down transistor M10 are connected with the pull-down node PD, second electrodes of the node pull-down transistor M9 and the output pull-down transistor M10 are connected with the first power-supply voltage terminal VSS, a first electrode of the node pull-down transistor M9 is connected with the pull-up node PU, and a first electrode of the output pull-down transistor M10 is connected with the output terminal OUTPUT. When the pull-down signal at the pull-down node PD is at the high voltage level, the node pull-down transistor M9 and the output pull-down transistor M10 are turned on, to respectively pull down the pull-up node PU and the output terminal OUTPUT to the power-supply voltage of the first power-supply voltage terminal VSS.

In an embodiment, for example, the output circuit 35 includes an output transistor M2 and a first capacitor C1 . A gate electrode of the output transistor M2 and a first terminal of the first capacitor C1 are connected with the pull-up node PU, a first electrode of the output transistor M2 is connected with the second clock signal terminal CLK, and a second electrode of the output transistor M2 and a second terminal of the first capacitor C1 are connected with the output terminal OUTPUT. When the pull-up signal at the pull-up node PU is at the high voltage level, the output transistor M2 is turned on, to output the second clock signal of the second clock signal terminal CLK to the output terminal OUTPUT.

In an embodiment, for example, the noise reduction circuit 36 includes a second capacitor C2. The second capacitor C2 has a first terminal connected with the pull-down node PD and a second terminal connected with the first power-supply voltage terminal VSS. When the pull-down signal at the pull-down node PD is at the high voltage level, the second capacitor C2 maintains the high voltage level, so that the node pull-down transistor M9 and the output pull-down transistor M10 are still turned on to continue pulling down a voltage of the pull-up node PU and a voltage of the output terminal OUTPUT. Thus, influence of the high voltage level of the second clock signal terminal CLK on the voltage of the pull-up node PU and the voltage of the output terminal OUTPUT through the gate source capacitor Cgs of the output transistor M2 is reduced, and noise at the pull-up node PU and the output terminal OUTPUT is reduced.

FIG. 5 shows another exemplary circuit structural diagram of a shift register according to an embodiment of the present disclosure.

As shown in FIG. 5, the exemplary circuit structural diagram differs from that of FIG. 4 in the noise reduction circuit 36. In an embodiment, for example, as shown in FIG. 5, the noise reduction circuit 36 includes a third capacitor C3. The third capacitor C3 has a first terminal connected with the pull-down node PD, and a second terminal connected with the second clock signal terminal CLK. When the pull-down signal at the pull-down node PD is at the high voltage level, the third capacitor C3 maintains the high voltage level, so that the node pull-down transistor M9 and the output pull-down transistor M10 are still turned on, to continue pulling down the voltage of the pull-up node PU and the voltage of the output terminal OUTPUT. Thus, influence of the high voltage level of the second clock signal terminal CLK on the voltage of the pull-up node PU and the voltage of the output terminal OUTPUT through the gate source capacitor Cgs of the output transistor M2 is reduced, and the noise at the pull-up node PU and the output terminal OUTPUT is reduced.

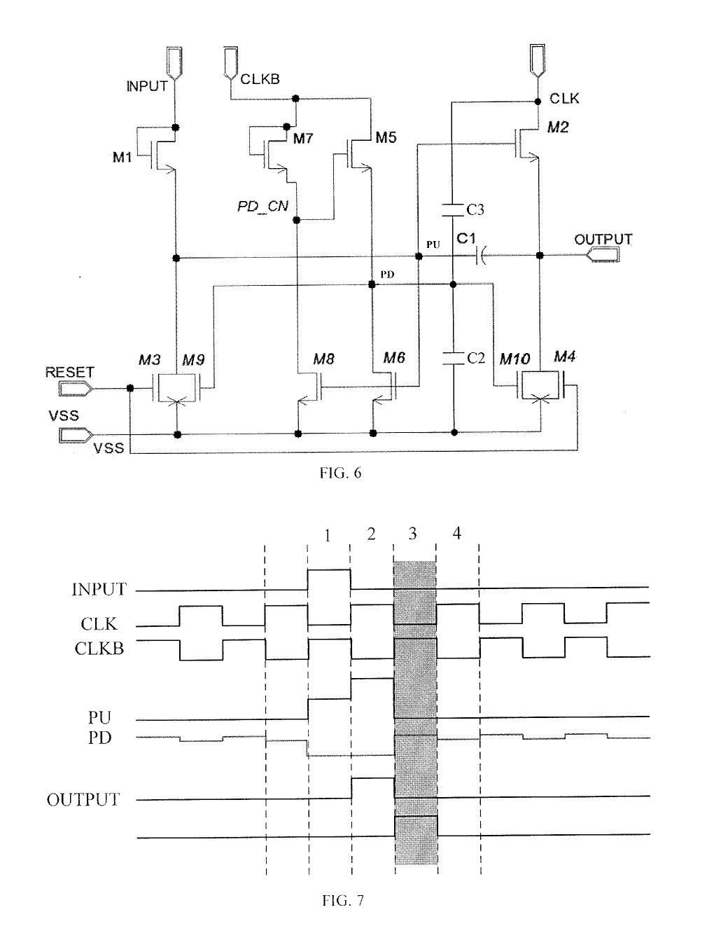

FIG. 6 shows yet another exemplary circuit structural diagram of a shift register according to an embodiment of the present disclosure.

As shown in FIG. 6, the exemplary circuit structural diagram differs from that of FIG. 4 in the noise reduction circuit 36. In an embodiment, for example, as shown in FIG. 6, the noise reduction circuit 36 includes the second capacitor C2 and the third capacitor C3. The second capacitor C2 has a first terminal connected with the pull-down node PD, and a second terminal connected with the first power-supply voltage terminal VSS. The third capacitor C3 has a first terminal connected with the pull-down node PD, and a second terminal connected with the second clock signal terminal CLK. When the pull-down signal at the pull-down node PD is at the high voltage level, the second capacitor C2 and the third capacitor C3 maintain the high voltage level, so that the node pull-down transistor M9 and the output pull-down transistor M10 are still turned on, to continue pulling down the voltage of the pull-up node PU and the voltage of the output terminal OUTPUT. Thus, influence of the high voltage level of the second clock signal terminal CLK on the voltage of the pull-up node PU and the voltage of the output terminal OUTPUT through the gate source capacitor Cgs of the output transistor M2 is reduced, and the noise at the pull-up node PU and the output terminal OUTPUT is reduced.

FIG. 7 shows an operation timing chart of the exemplary circuit of the shift register in FIG. 6. Hereinafter, an operation method of the shift register in FIG. 6 will be described with reference to FIG. 6 and FIG. 7.

In a first phase 1 (an input phase), an input terminal INPUT is at a high voltage level, and an input transistor T1 is turned on to transmit the high voltage level of the input terminal INPUT to a pull-up node PU. At this time, the pull-up node PU is at a first high voltage, so that an output transistor M2 is turned on. Since a second clock signal of a second clock signal terminal CLK is at a low voltage level, an output terminal OUTPUT outputs a low voltage level. In addition, in this phase, since the pull-up node PU is at the high voltage level, a second pull-down control transistor M6 and a fourth pull-down control transistor M8 are turned on, so that a pull-down node PD is at the low voltage level, and correspondingly, a node pull-down transistor M9 and an output pull-down transistor M10 are both turned off. In addition, in the phase, a reset signal of a reset signal terminal RESET is at the low voltage level, and a node reset transistor M3 is turned off.

In a second phase 2 (an output phase), the input terminal INPUT is at the low voltage level, an input transistor M1 is turned off, the reset signal terminal RESET is at the low voltage level, the node reset transistor M3 maintains being turned off, the pull-up node PU continues to make the output transistor M2 to be turned on, the second clock signal of the second clock signal terminal CLK is at the high voltage level, and the output terminal OUTPUT outputs a high voltage level. Due to a voltage coupling effect of the first capacitor C1, at this time, the pull-up node PU is lifted from a first high voltage to a second high voltage. In addition, in the phase, since the pull-up node PU is still at the high voltage level, the second pull-down control transistor M6 and the fourth pull-down control transistor M8 maintain being turned on, the pull-down node PD is still at the low voltage level, and correspondingly, the node pull-down transistor M9 and the output pull-down transistor M10 both maintain being turned off.

In a third phase 3 (a reset phase), the input terminal INPUT is at the low voltage level, the input transistor M1 maintains being turned off, and the reset signal of the reset signal terminal RESET is at the high voltage level. The node reset transistor M3 and the output reset transistor M4 are turned on, to respectively pull down the pull-up signal at the pull-up node PU and the output signal of the output terminal OUTPUT to the power-supply voltage of the first power-supply voltage terminal VSS. In addition, in the phase, since the pull-up node PU is at the low voltage level, the second pull-down control transistor M6 and the fourth pull-down control transistor M8 are both turned off. Since the first clock signal of the first clock signal terminal CLKB is at the high voltage level, the first pull-down control transistor MS and the third pull-down control transistor M7 are both turned on, so that the pull-down node PD transits from the low voltage level to the high voltage level. Correspondingly, the node pull-down transistor M9 and the output pull-down transistor M10 are both turned on, to pull down the pull-up signal at the pull-up node PU and the output signal of the output terminal OUTPUT to the power-supply voltage of the first power-supply voltage terminal VSS. Since the pull-down node PD is at the high voltage level, the second capacitor C2 and the third capacitor C3 are charged at this time.

In a fourth phase 4 (a holding phase), the first clock signal of the first clock signal terminal CLKB is at the low voltage level, and the first pull-down control transistor MS and the third pull-down control transistor M7 are both turned off. Since the pull-up node PU is at the low voltage level, the second pull-down control transistor M6 and the fourth pull-down control transistor M8 both maintain being turned off. The second capacitor C2 and the third capacitor C3 simultaneously maintain the voltage of the pull-down node PD, so that the voltage of the pull-down node PD maintains being at the high voltage level; and correspondingly, the node pull-down transistor M9 and the output pull-down transistor M10 are both turned on, to maintain pulling down the pull-up node PU and the output terminal OUTPUT to the power-supply voltage of the first power-supply voltage terminal VSS. Thus, influence of the high voltage level of the second clock signal terminal CLK on the voltage of the pull-up node PU and the voltage of the output terminal OUTPUT through the gate source capacitor Cgs of the output transistor M2 is reduced, and the noise at the pull-up node PU and the output terminal OUTPUT is reduced.

The first power-supply voltage terminal VSS is a low power-supply voltage terminal.

Then, before a next frame arrives, the pull-up node PU is at the low voltage level, the pull-down node PD is at the high voltage level, and the node pull-down transistor M9 and the output pull-down transistor M10 are in a turn-on state, which can continue reducing the noise for the pull-up node PU and the output terminal OUTPUT, so as to ensure stability of outputting a low-voltage signal of the output terminal OUTPUT. When the next frame arrives, after the shift register receives the high voltage level signal of the input terminal INPUT, the above-described first phase is re-executed.

It can be seen from FIG. 7 that the first clock signal of the first clock signal terminal CLKB and the second clock signal of the second clock signal terminal CLK have inverted phases.

The present disclosure further provides an operation method for the above-described shift register. Hereinafter, the method will be described in conjunction with FIG. 3 and FIG. 7. In an embodiment, for example, as shown in FIG. 3, the shift register includes an input circuit 31, a reset circuit 32, a pull-down control circuit 33, a pull-down circuit 34, an output circuit 35 and a noise reduction circuit 36. The operation method of the shift register comprises:

transmitting, by the input circuit 31, a received input signal to the pull-up node PU;

pulling down, by the reset circuit 32, a pull-up signal at the pull-up node PU to a power-supply voltage of a first power-supply voltage terminal VSS, and pulling down an output signal of an output terminal OUTPUT of the shift register to the power-supply voltage of the first power-supply voltage terminal VSS;

controlling, by the pull-down control circuit 33, whether the pull-down circuit 34 operates or not;

pulling down, by the pull-down circuit 34, the output terminal OUTPUT and the pull-up node PU of the shift register to the power-supply voltage of the first power-supply voltage terminal VSS;

outputting, by the output circuit 35, the second clock signal of the second clock signal terminal CLK to the output terminal OUTPUT of the shift register; and

reducing, by the noise reduction circuit 36, noise at the output terminal OUTPUT of the shift register through maintaining a voltage level of a pull-down node PD.

For example, the first power-supply voltage terminal VSS is a low power-supply voltage terminal, and the first clock signal of the first clock signal terminal CLKB and the second clock signal of the second clock signal terminal CLK have inverted phases.

What are described above is related to the illustrative embodiments of the disclosure only and not limitative to the scope of the disclosure; any changes or replacements easily for those technical personnel who are familiar with this technology in the field to envisage in the scopes of the disclosure, should be in the scope of protection of the present disclosure. Therefore, the scopes of the disclosure are defined by the accompanying claims.

The present application claims the priority of the Chinese Patent Application No. 201610323870.1 filed on May 16, 2016, which is incorporated herein by reference in its entirety as part of the disclosure of the present application.

1. A shift register, comprising:
an input circuit, including a first terminal connected with an input terminal of the shift register for receiving an input signal from the input terminal and a second terminal connected with a pull-up node;
a reset circuit, including a first terminal connected with a reset signal terminal, a second terminal connected with the pull-up node, a third terminal connected with a first power-supply voltage terminal, and a fourth terminal connected with an output terminal of the shift register;
a pull-down control circuit, including a first terminal connected with a first clock signal terminal, a second terminal connected with the pull-up node, a third terminal connected with a pull-down node, and a fourth terminal connected with the first power-supply voltage terminal;
a pull-down circuit, including a first terminal connected with the pull-down node, a second terminal connected with the output terminal of the shift register, a third terminal connected with the pull-up node, and a fourth terminal connected with the first power-supply voltage terminal;
an output circuit, including a first terminal connected with the pull-up node, a second terminal connected with a second clock signal terminal, and a third terminal connected with the output terminal of the shift register; and
a noise reduction circuit, connected with the pull-down node and configured for reducing noise at the output terminal of the shift register by maintaining a voltage level of the pull-down node.

2. The shift register according to claim 1, wherein the input circuit includes an input transistor, a gate electrode and a first electrode of the input transistor are connected with the input terminal, and a second electrode of the input transistor is connected with the pull-up node.

3. The shift register according to claim 1, wherein the output circuit includes an output transistor and a first capacitor, a gate electrode of the output transistor and a first terminal of the first capacitor are connected with the pull-up node, a first electrode of the output transistor is connected with the second clock signal terminal, and a second electrode of the output transistor and a second terminal of the first capacitor are connected with the output terminal.

4. The shift register according to claim 1, wherein the reset circuit includes:
a node reset transistor, including a gate electrode connected with the reset signal terminal, a first electrode connected with the pull-up node, and a second electrode connected with the first power-supply voltage terminal; and
an output reset transistor, including a gate electrode connected with the reset signal terminal, a first electrode connected with the output terminal, and a second electrode connected with the first power-supply voltage terminal.

5. The shift register according to claim 1, wherein the pull-down control circuit includes:
a first pull-down control transistor, including a gate electrode connected with a pull-down control node, a first electrode connected with the first clock signal terminal, and a second electrode connected with the pull-down node;
a second pull-down control transistor, including a gate electrode connected with the pull-up node, a first electrode connected with the pull-down node, and a second electrode connected with the first power-supply voltage terminal;
a third pull-down control transistor, including a gate electrode and a first electrode connected with the first clock signal terminal, and a second electrode connected with the pull-down control node; and
a fourth pull-down control transistor, including a gate electrode connected with the pull-up node, a first electrode connected with the pull-down control node, and a second electrode connected with the first power-supply voltage terminal.

6. The shift register according to claim 1, wherein the pull-down circuit includes a node pull-down transistor and an output pull-down transistor, gate electrodes of the node pull-down transistor and the output pull-down transistor are connected with the pull-down node, second electrodes of the node pull-down transistor and the output pull-down transistor are connected with the first power-supply voltage terminal, a first electrode of the node pull-down transistor is connected with the pull-up node, and a first electrode of the output pull-down transistor is connected with the output terminal.

7. The shift register according to claim 1, wherein the noise reduction circuit includes a second capacitor, which includes a first terminal connected with the pull-down node and a second terminal connected with the first power-supply voltage terminal.

8. The shift register according to claim 1, wherein the noise reduction circuit includes a third capacitor, which includes a first terminal connected with the pull-down node and a second terminal connected with the second clock signal terminal.

9. The shift register according to claim 1, wherein the noise reduction circuit includes:
a second capacitor, including a first terminal connected with the pull-down node and a second terminal connected with the first power-supply voltage terminal; and
a third capacitor, including a first terminal connected with the pull-down node and a second terminal connected with the second clock signal terminal.

10. The shift register according to claim 2, wherein the transistors are all N-type transistors.

11. The shift register according to claim 1, wherein the second clock signal of the second clock signal terminal and the first clock signal of the first clock signal terminal have inverted phases.

12. The shift register according to claim 1, wherein the first power-supply voltage terminal is a low power-supply voltage terminal.

13. An operation method of a shift register, the shift register comprising an input circuit, a reset circuit, a pull-down control circuit, a pull-down circuit, an output circuit and a noise reduction circuit, the method comprising:
transmitting, by the input circuit, a received input signal to a pull-up node;
pulling down, by the reset circuit, a pull-up signal at the pull-up node to a power-supply voltage of a first power-supply voltage terminal, and pulling down an output signal of an output terminal of the shift register to a power-supply voltage of the first power-supply voltage terminal;
controlling, by the pull-down control circuit, whether the pull-down circuit operates or not;
pulling down, by the pull-down circuit, the output terminal and the pull-up node of the shift register to the power-supply voltage of the first power-supply voltage terminal;
outputting, by the output circuit, a second clock signal of a second clock signal terminal to the output terminal of the shift register; and
reducing, by the noise reduction circuit, noise at the output terminal of the shift register through maintaining a voltage level of a pull-down node.

14. The operation method according to claim 13, wherein the first power-supply voltage terminal is a low power-supply voltage terminal.

15. The operation method according to claim 13, wherein the second clock signal of the second clock signal terminal and the first clock

16. The shift register according to claim 2, wherein the output circuit includes an output transistor and a first capacitor, a gate electrode of the output transistor and a first terminal of the first capacitor are connected with the pull-up node, a first electrode of the output transistor is connected with the second clock signal terminal, and a second electrode of the output transistor and a second terminal of the first capacitor are connected with the output terminal.

17. The shift register according to claim 2, wherein the reset circuit includes:
a node reset transistor, including a gate electrode connected with the reset signal terminal, a first electrode connected with the pull-up node, and a second electrode connected with the first power-supply voltage terminal; and
an output reset transistor, including a gate electrode connected with the reset signal terminal, a first electrode connected with the output terminal, and a second electrode connected with the first power-supply voltage terminal.

18. The shift register according to claim 2, wherein the pull-down control circuit includes:
a first pull-down control transistor, including a gate electrode connected with a pull-down control node, a first electrode connected with the first clock signal terminal, and a second electrode connected with the pull-down node;
a second pull-down control transistor, including a gate electrode connected with the pull-up node, a first electrode connected with the pull-down node, and a second electrode connected with the first power-supply voltage terminal;
a third pull-down control transistor, including a gate electrode and a first electrode connected with the first clock signal terminal, and a second electrode connected with the pull-down control node; and
a fourth pull-down control transistor, including a gate electrode connected with the pull-up node, a first electrode connected with the pull-down control node, and a second electrode connected with the first power-supply voltage terminal.

19. The shift register according to claim 2, wherein the pull-down circuit includes a node pull-down transistor and an output pull-down transistor, gate electrodes of the node pull-down transistor and the output pull-down transistor are connected with the pull-down node, second electrodes of the node pull-down transistor and the output pull-down transistor are connected with the first power-supply voltage terminal, a first electrode of the node pull-down transistor is connected with the pull-up node, and a first electrode of the output pull-down transistor is connected with the output terminal.

20. The shift register according to claim 2, wherein the noise reduction circuit includes a second capacitor, which includes a first terminal connected with the pull-down node and a second terminal connected with the first power-supply voltage terminal.
